(19) United States
(12) Patent Application Publication
(10) Pub. No.: US 2026/0011646 A1
(43) Pub. Date: Jan. 8, 2026

(54) STRUCTURE AND FORMATION METHOD OF INTEGRATED CHIPS PACKAGE WITH THERMAL CONDUCTIVE ELEMENT

(71) Applicant: Taiwan Semiconductor Manufacturing Company, Ltd., Hsinchu (TW)

(72) Inventors: Cheng-Chieh HSIEH, Tainan (TW); Yu-Jen LIEN, Tainan City (TW); Ke-Han SHEN, Chiayi City (TW); Hung-Yi KUO, Taipei City (TW)

(21) Appl. No.: 18/763,089

(22) Filed: Jul. 3, 2024

(51) Int. Cl. H01L 23/538; H01L 21/48; H01L 23/00; H01L 23/14; H01L 23/373; H01L 23/48; H01L 25/00; H01L 25/065

(52) U.S. Cl. CPC H01L 23/5384; H01L 21/486; H01L 23/14; H01L 23/3732; H01L 24/08; H01L 25/0657; H01L 25/50; H01L 23/481; H01L 24/80; H01L 24/97; H01L 2224/08235; H01L 2224/80006; H01L 2224/95001

(57) ABSTRACT

A package structure and a formation method are provided. The method includes forming multiple patterned material elements over a carrier substrate, and the patterned material elements are more thermal conductive than copper. The method also includes forming a protective layer laterally surrounding each of the patterned material elements. The method further includes bonding a chip-containing structure to a first patterned material element of the patterned material elements through dielectric-to-dielectric bonding and metal-to-metal bonding.

### BACKGROUND

The semiconductor integrated circuit (IC) s industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1V are cross-sectional views of various stages of a process for forming a portion of a package structure, in accordance with some embodiments.

FIG. 1I-1 is a top view of an intermediate stage of a process for forming a portion of a package structure, in accordance with some embodiments.

FIG. 1J-1 is a top view of an intermediate stage of a process for forming a portion of a package structure, in accordance with some embodiments.

FIG. 1M-1 is a top view of an intermediate stage of a process for forming a portion of a package structure, in accordance with some embodiments.

FIGS. 2A-2F are cross-sectional views of various stages of a process for forming a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

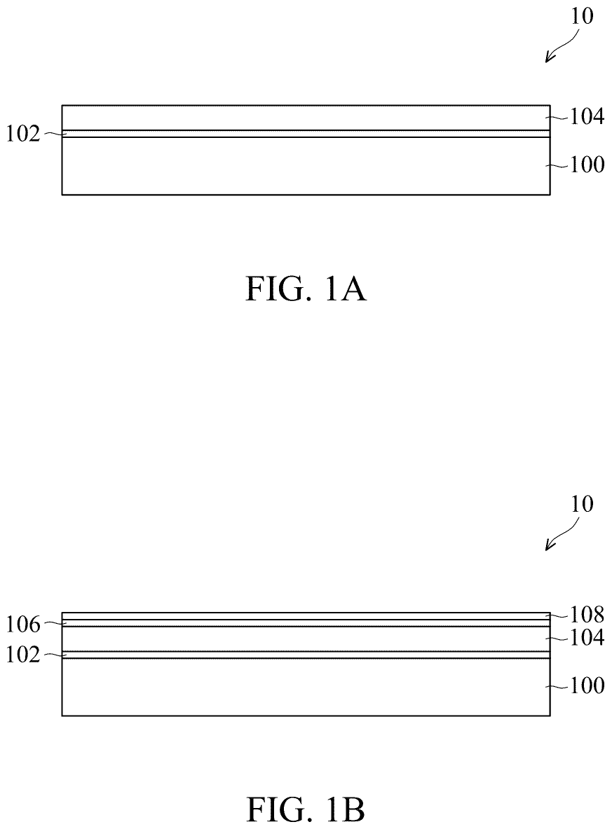

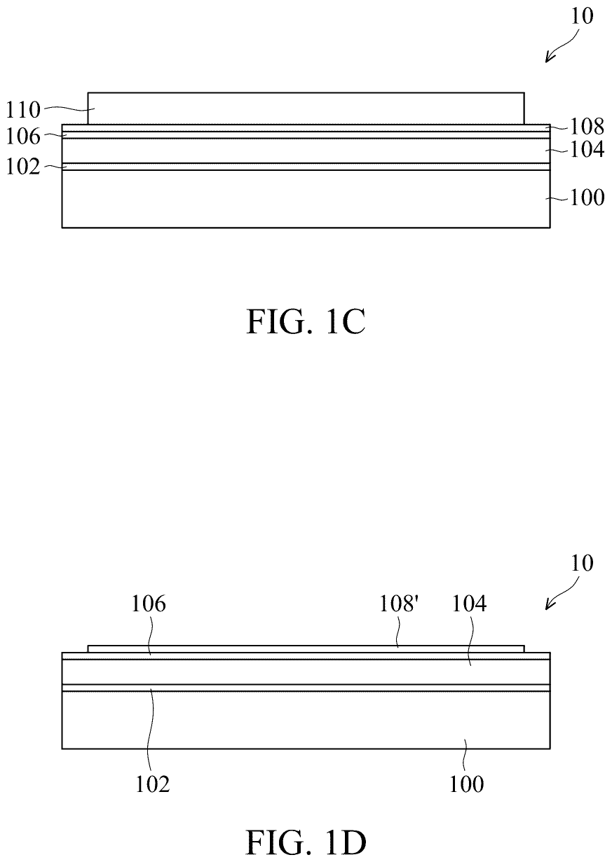

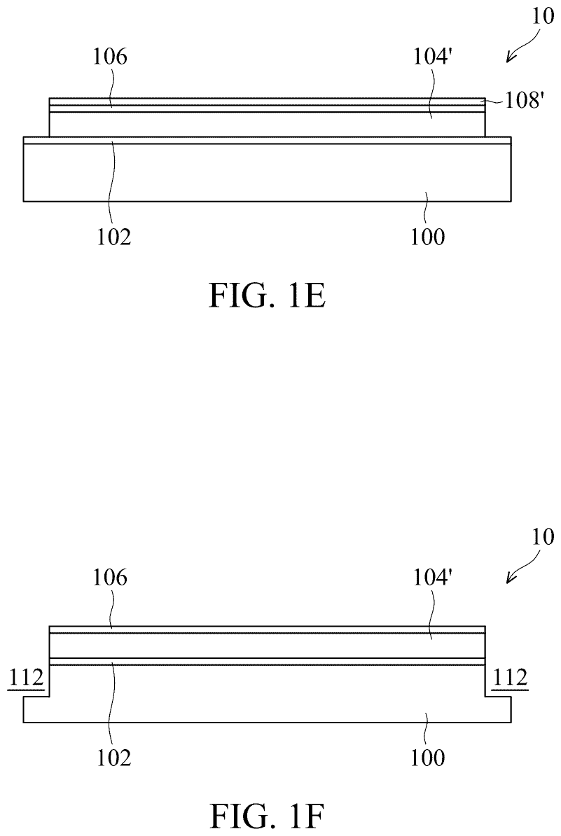

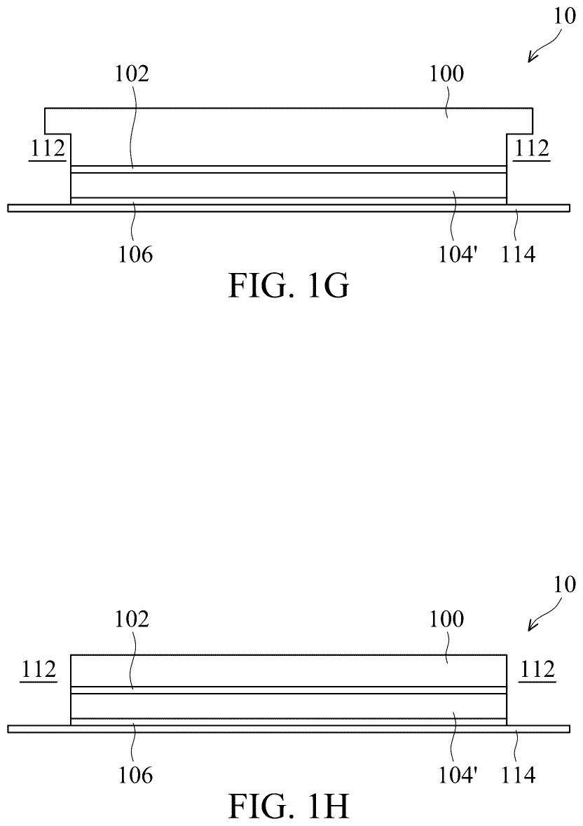

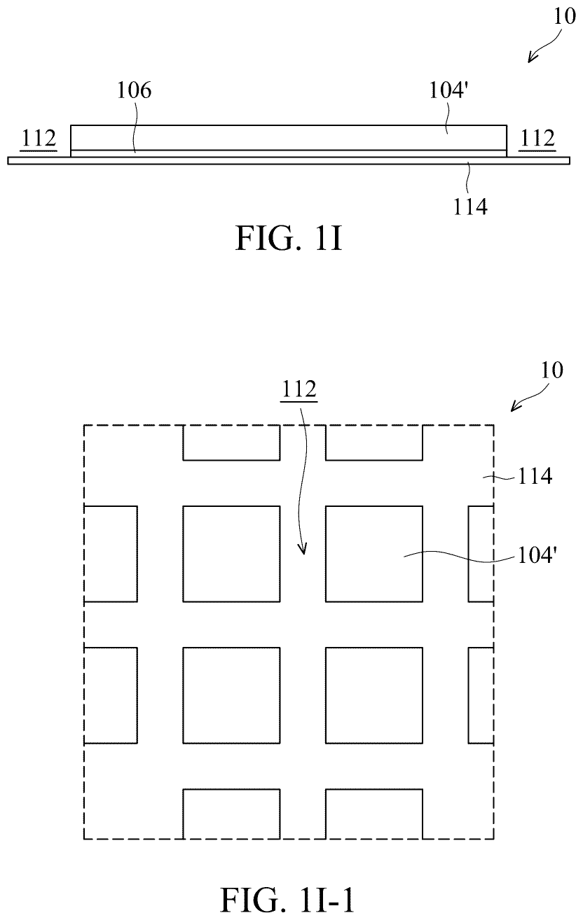

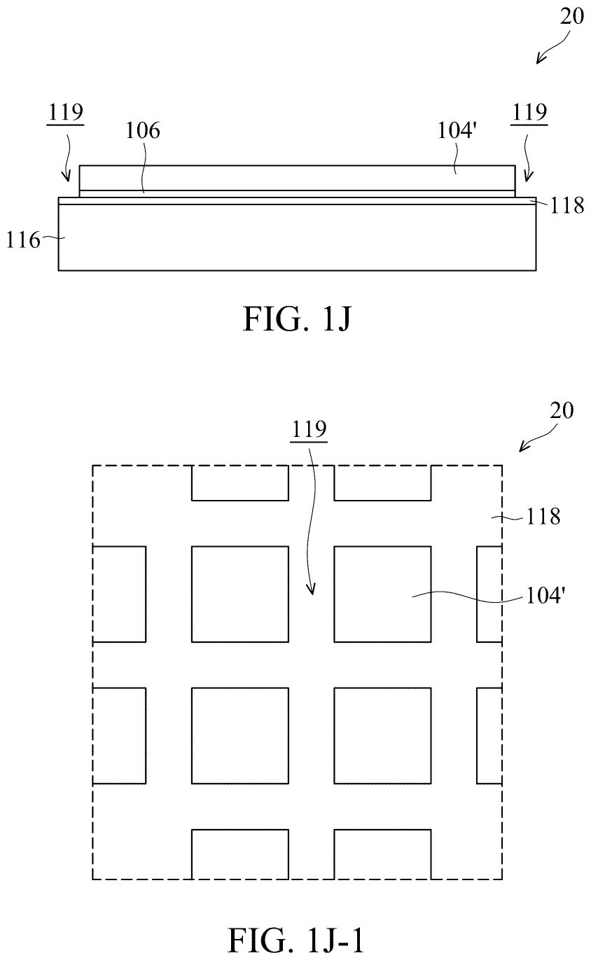

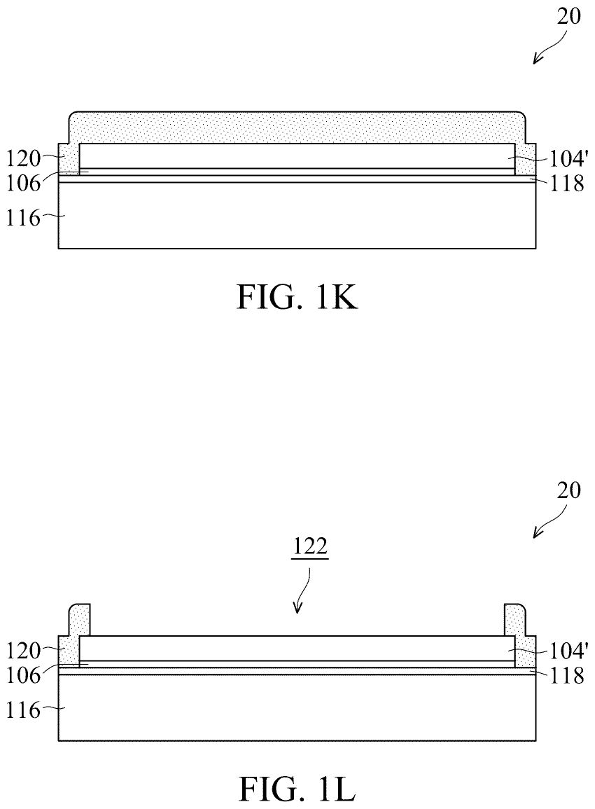

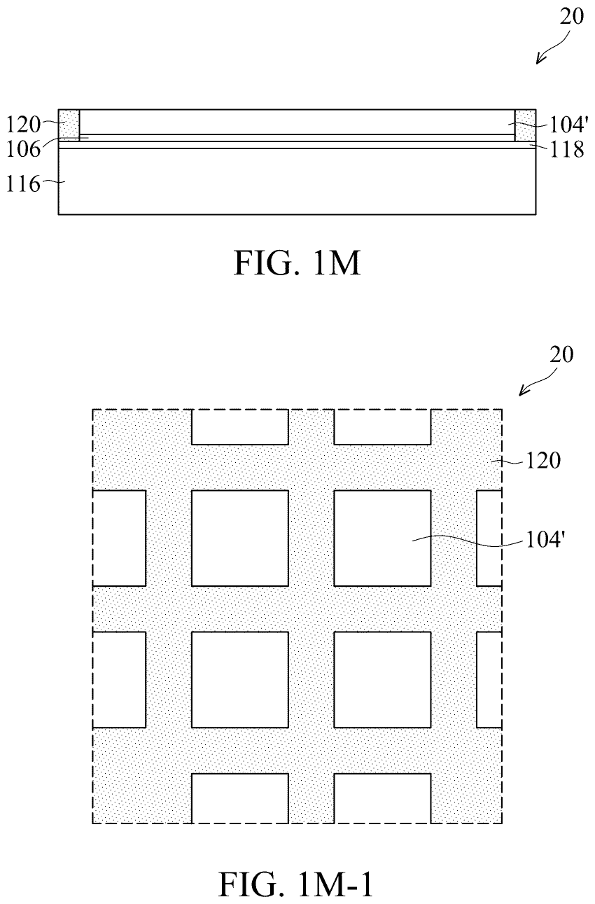

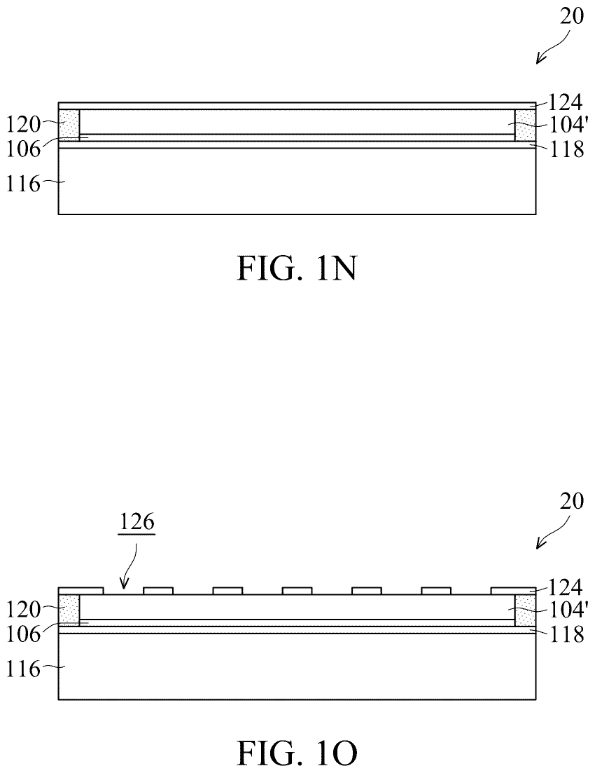

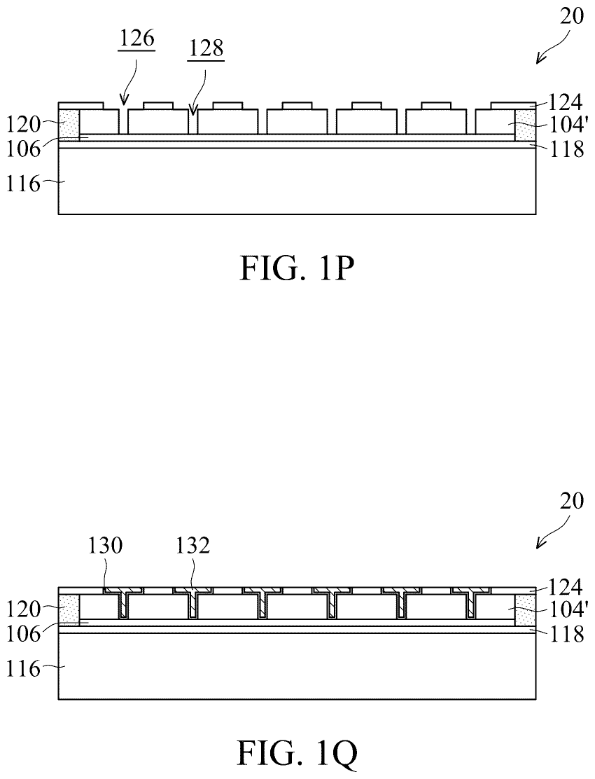

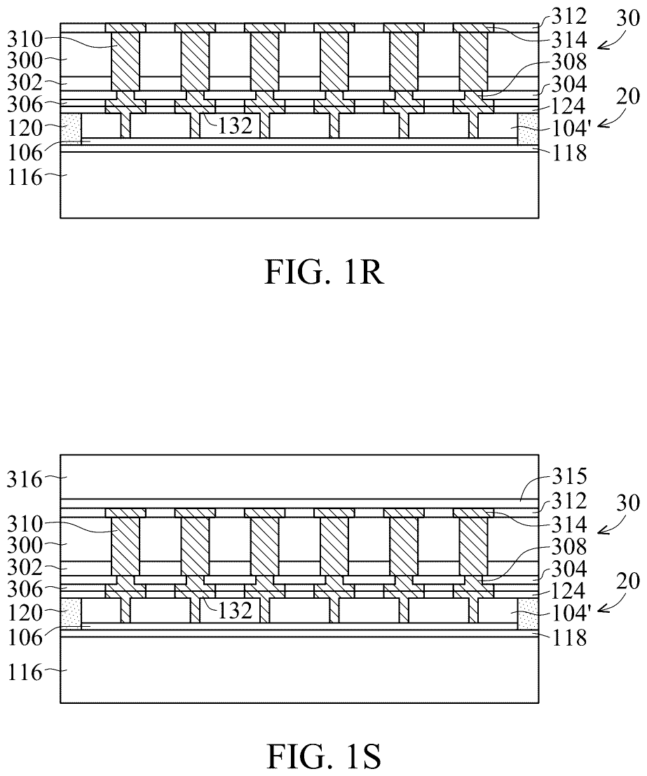

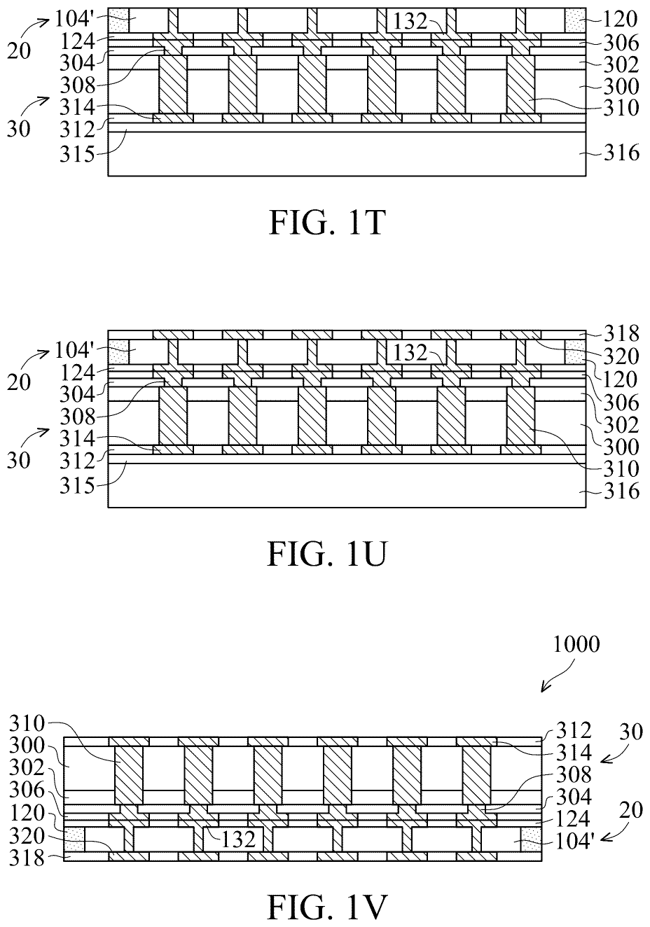

FIGS. 1A-1V are cross-sectional views of various stages of a process for forming a portion of a package structure, in accordance with some embodiments. As shown in FIG. 1A, various stages of a process for forming a portion of a thermal conductive wafer 10 is illustrated. As shown in FIG. 1A, a material layer 104 is formed over a carrier substrate 100, in accordance with some embodiments. In some embodiments, the carrier substrate 100 is a semiconductor wafer such as a silicon wafer. For example, the carrier substrate 100 is a silicon wafer with a diameter that is in a range from about 4 inches to about 8 inches.

In some embodiments, a seed layer 102 is deposited over the carrier substrate 100 before the formation of the material layer 104. The seed layer 102 may be used to assist in the formation of the material layer 104. The seed layer 102 may be made of or include a carbon-containing material such as silicon carbide. The seed layer 102 may be deposited using a chemical vapor deposition (CVD) process, a physical vapor deposition (PVD) process, an atomic layer deposition (ALD) process, another applicable process, or a combination thereof.

In some embodiments, the material layer 104 is then deposited on the seed layer 102, as shown in FIG. 1A. In some embodiments, the material layer 104 has a high thermal conductivity. In some embodiments, the material layer 104 has a thermal conductivity greater than 100 W/mK. In some embodiments, the material layer 104 has a thermal conductivity greater than the thermal conductivity of copper. In some embodiments, the material layer 104 has a thermal conductivity greater than 400 W/mK, or greater than 2000 W/mK. The material layer 104 may be made of diamond, graphene, silver, another suitable material, or a combination thereof. The material layer 104 may be deposited using a CVD process, an ALD process, a PVD process, another applicable process, or a combination thereof.

In some embodiments, the material layer 104 is a diamond-containing layer such as a diamond layer. The deposition of the diamond-containing layer may involve a CVD process. In some embodiments, in the CVD process, a mixture of gases containing a carbon source gas (such as methane) is introduced into a reaction chamber. Under high temperature (such as in a range from about 800 degrees C. to about 1200 degrees C.) and high pressure, the carbon source gas decomposes, and diamond crystals are then deposited on the surface of the seed layer 102 to form the material layer 104.

As shown in FIG. 1B, a bonding layer 106 and a mask layer 108 are sequentially formed over the material layer 104, in accordance with some embodiments. The bonding layer 106 may be made of or include silicon oxide, oxide-containing materials, silicon nitride, nitride-containing materials, silicon oxynitride, polymer, other suitable materials, or a combination thereof. The mask layer 108 may be used for forming a hard mask. The mask layer 108 may be made of or include nickel, silicon nitride, aluminum nitride, chromium nitride, another suitable material, or a combination thereof.

As shown in FIG. 1C, a patterned photoresist layer 110 is formed over the mask layer 108, in accordance with some embodiments. The patterned photoresist layer 110 has multiple openings that partially expose the mask layer 108. The patterned photoresist layer 110 may be used to assist in the subsequent patterning of the mask layer 108.

Afterwards, one or more etching processes are used to remove the portions of the mask layer 108 that are exposed by the openings of the patterned photoresist layer 110. Then, the patterned photoresist layer 110 is removed. As a result, the structure shown in FIG. 1D is formed, in accordance with some embodiments. The mask layer 108 is patterned to form a mask element 108′, as shown in FIG. 1D.

Afterwards, with the mask element 108′ as an etching mask, the bonding layer 106 and the material layer 104 are partially removed using one or more etching processes. In some embodiments, the etching processes used for partially remove the material layer 104 include one or more dry etching processes. In some embodiments, the one or more dry etching processes involve the use of plasma beams. A plasma dicing operation may be used. As a result, the structure shown in FIG. 1E is formed, in accordance with some embodiments. The material layer 104 is patterned to form multiple thermal conductive elements 104′. One of the thermal conductive elements 104′ is shown in FIG. 1E. In some embodiments, the seed layer 102 is partially exposed.

Afterwards, with the mask element 108′ as an etching mask, the seed layer 102 and the carrier substrate 100 are partially removed using one or more etching processes. Then, the mask element 108′ is removed. As a result, the structure shown in FIG. 1F is formed, in accordance with some embodiments. Multiple trenches 112 are formed in the carrier substrate 100.

As shown in FIG. 1G, the structure shown in FIG. 1F is turned upside down and attached onto a carrier tape 114, in accordance with some embodiments. Afterwards, the carrier substrate 100 is thinned to expose the trenches 112, as shown in FIG. 1H in accordance with some embodiments. The carrier substrate 100 may be thinned using a chemical mechanical polishing (CMP) process, a grinding process, an etching process, another applicable process, or a combination thereof.

As shown in FIG. 1I, the structure shown in FIG. 1H is further thinned to remove the carrier substrate 100 and the seed layer 102, in accordance with some embodiments. As a result, the thermal conductive elements 104′ are exposed. In FIG. 1I, one of the thermal conductive elements 104′ is shown.

FIG. 1I-1 is a top view of an intermediate stage of a process for forming a portion of a package structure, in accordance with some embodiments. As shown in FIG. 1I-1, the top view of a portion of the carrier tape 114 and some of the thermal conductive elements 104′ are shown. As illustrated in FIGS. 11 and 1I-1, the thermal conductive elements 104 on the carrier tape 114 are spaced apart from each other by the trenches 112.

FIG. 1J-1 is a top view of an intermediate stage of a process for forming a portion of a package structure, in accordance with some embodiments. As shown in FIGS. 1J and 1J-1, various stages of a process for forming a portion of a reconstructed thermal conductive wafer 20 is illustrated. As shown in FIGS. 1J and 1J-1, the thermal conductive elements 104′ are picked from the carrier tape 114 and then attached onto a carrier substrate 116, in accordance with some embodiments. As a result, a reconstructed thermal conductive wafer 20 is formed.

A bonding layer 118 may be used to attach the thermal conductive elements 104′ to the carrier substrate 116. The material of the bonding layer 118 may be the same as or similar to that of the bonding layer 106.

In some embodiments, the carrier substrate 116 is a semiconductor wafer such as a silicon wafer. In some embodiments, the carrier substrate 100 and the carrier substrate 116 are semiconductor wafers with different diameters. In some embodiments, the carrier substrate 116 is wider than the carrier substrate 100. For example, the carrier substrate 116 is a silicon wafer with a diameter that is in a range from about 8 inches to about 22 inches.

In some embodiments, the reconstructed thermal conductive wafer 20 has a diameter that is larger than that of the thermal conductive wafer 10. In some embodiments, some other thermal conductive elements from another thermal conductive wafer that is similar to the thermal conductive wafer 10 are also disposed over the carrier substrate 116 to form the reconstructed thermal conductive wafer 20.

As shown in FIG. 1J-1, the top view of a portion of the bonding layer 118 and some of the thermal conductive elements 104′ are shown. As illustrated in FIGS. 1J and 1J-1, the thermal conductive elements 104 over the carrier substrate 116 and the bonding layer 118 are spaced apart from each other by multiple trenches 119.

As shown in FIG. 1K, a protective layer 120 is deposited over the carrier substrate 116 to cover the thermal conductive elements 104′ and to overfill the trenches 119, in accordance with some embodiments. The protective layer 120 may be made of or include silicon oxide, silicon oxynitride, carbon-containing silicon oxide, another suitable material, or a combination thereof. The protective layer 120 may be deposited using a CVD process, a flowable chemical vapor deposition (FCVD) process, an ALD process, another applicable process, or a combination thereof.

Afterwards, the protective layer 120 is patterned to form multiple openings 122 that partially expose the thermal conductive elements 104′, in accordance with some embodiments. As a result, the structure shown in FIG. 1L is formed. In FIG. 1L, one of the openings 122 and one of the thermal conductive elements 104′ are shown. The openings 122 may be formed using one or more photolithography processes and one or more etching processes. The formation of the openings 122 may facilitate the subsequent planarization of the protective layer 120.

As shown in FIG. 1M, the protective layer 120 is planarized, in accordance with some embodiments. After the planarization of the protective layer 120, the topmost surfaces of the protective layer 120 is substantially coplanar with the surfaces of the thermal conductive element 104′, as shown in FIG. 1M. The planarization process may include a CMP process, a grinding process, an etching process, another applicable process, or a combination thereof.

FIG. 1M-1 is a top view of an intermediate stage of a process for forming a portion of a package structure, in accordance with some embodiments. As shown in FIG. 1M-1, the top view of a portion of the protective layer 120 and some of the thermal conductive elements 104′ are shown. As illustrated in FIGS. 1M and 1M-1, the protective layer 120 laterally surrounds the thermal conductive elements 104′. The thermal conductive elements 104′ are spaced apart from each other by the protective layer 120. In some embodiments, the protective layer 120 extends across opposite edges of each of the thermal conductive elements 104′.

As shown in FIG. 1N, a dielectric bonding structure 124 is formed over the protective layer 120 and the thermal conductive element 104′, in accordance with some embodiments. The dielectric bonding structure 124 may include one or more dielectric layers. The dielectric bonding structure 124 may be made of or include silicon oxide, carbon-containing silicon oxide, silicon oxynitride, silicon nitride, carbon-containing silicon oxynitride, carbon-containing silicon nitride, one or more other suitable materials, or a combination thereof. In some embodiments, the dielectric bonding structure 124 is free of polymer material. The dielectric bonding structure 124 may be deposited using a CVD process, a PVD process, an ALD process, an FCVD process, another applicable process, or a combination thereof.

As shown in FIG. 1O, the dielectric bonding structure 124 is patterned to form multiple openings 126 that expose the thermal conductive element 104′, in accordance with some embodiments. The dielectric bonding structure 124 may be patterned using one or more photolithography processes and one or more etching processes.

As shown in FIG. 1P, the thermal conductive element 104′ is partially removed to form multiple through-holes 128 in the thermal conductive element 104′, in accordance with some embodiments. In some embodiments, the through-holes 128 penetrate through the thermal conductive element 104′ and expose the bonding layer 106. The formation of the through-holes 128 may involve one or more photolithography processes and one or more etching processes.

As shown in FIG. 1Q, multiple barrier elements 130 and multiple metal bonding structures 132 are formed, in accordance with some embodiments. The barrier elements 130 may be made of or include titanium nitride, silicon oxide, silicon nitride, silicon oxynitride, another suitable material, or a combination thereof. The metal bonding structures 132 may be made of or include copper, aluminum, cobalt, gold, another suitable material, or a combination thereof. The metal bonding structures 132 may also function as conductive vias that establish electrical connections between elements over opposite sides of the thermal conductive element 104′.

In some embodiments, a barrier layer is deposited over the dielectric bonding structure 124 and the sidewalls and bottoms of the openings 126 and the through-holes 128. The barrier layer may be deposited using a CVD process, an ALD process, a PVD process, another applicable process, or a combination thereof. Afterwards, a conductive material layer is formed over the barrier layer to overfill the openings 126 and the through-holes 128. The conductive material layer may be formed using an electrochemical plating (ECP) process, a CVD process, another applicable process, or a combination thereof.

Afterwards, a planarization process is used to remove the portions of the barrier layer and the conductive material layer that are outside of the openings 126 and the through-holes 128. As a result, the remaining portions of the barrier layer and the remaining portions of the conductive material layer form the barrier elements 130 and the metal bonding structures 132, respectively. The planarization process may include a CMP process or another applicable process.

In some embodiments, a CMP process is used to ensure that the top surfaces of the metal bonding structures 132 and the top surface of the dielectric bonding structure 124 are substantially coplanar. The planarization process may help to provide the reconstructed thermal conductive wafer 20 with a highly planarized bonding surface.

As shown in FIG. 1R, a chip-containing structure 30 is bonded to the reconstructed thermal conductive wafer 20 through dielectric-to-dielectric bonding and metal-to-metal bonding, in accordance with some embodiments. In some embodiments, the chip-containing structure 30 extends across the outermost edges of the thermal conductive element 104′.

In some embodiments, the chip-containing structure 30 is a semiconductor wafer that includes multiple semiconductor chips. After a subsequent saw operation, multiple semiconductor chips that are separated from each other may be obtained. The bonding between the chip-containing structure 30 and the reconstructed thermal conductive wafer 20 is achieved using a wafer-on-wafer (WoW) bonding process.

In some other embodiments, the chip-containing structure 30 is a single semiconductor chip. The bonding between the chip-containing structure 30 and the reconstructed thermal conductive wafer 20 is achieved using a chip-on-wafer (CoW) bonding process. In these cases, multiple chip-containing structures 30 are bonded to the reconstructed thermal conductive wafer 20. A filling layer may then be formed to fill the gaps between the chip-containing structures 30.

In some embodiments, the chip-containing structure 30 includes a semiconductor substrate 300. In some embodiments, the semiconductor substrate 300 is a bulk semiconductor substrate, such as a semiconductor wafer. The semiconductor substrate 300 may include silicon or other elementary semiconductor materials such as germanium. The semiconductor substrate 300 may be un-doped or doped (e.g., p-type, n-type, or a combination thereof). In some embodiments, the semiconductor substrate 300 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 300 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 300 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 300 includes a multi-layered structure. For example, the semiconductor substrate 300 includes a silicon-germanium layer formed on a bulk silicon layer.

Various device elements are formed in or over the semiconductor substrate 300. In some embodiments, the device elements are formed in the device region 302, as shown in FIG. 1R. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or other suitable elements. Various processes may be used to form the various device elements, including deposition, etching, implantation, photolithography, annealing, and/or other suitable processes.

In some embodiments, the chip-containing structure 30 includes a front-side interconnection portion 304. The front-side interconnection portion 304 includes multiple dielectric layers and multiple conductive features surrounded by the dielectric layers. The conductive features may include conductive contacts, conductive lines, and conductive vias.

The device elements in the device region 302 of the chip-containing structure 30 may be interconnected by the front-side interconnection portion 304 to form integrated circuit devices, such as a logic device, a memory device (e.g., static random access memory, SRAM), a radio frequency (RF) device, an input/output (I/O) device, a system-on-chip (SoC) device, one or more other types of devices, or a combination thereof.

In some embodiments, the chip-containing structure 30 includes multiple through-chip vias 310, as shown in FIG. 1R. Each of the through-chip vias 310 may be electrically connected to one or more of the conductive features formed in the front-side interconnection portion 304. In some embodiments, an insulating layer is formed between the semiconductor substrate 300 and the through-chip vias 310, so as to prevent short circuiting between the through-chip vias 310 and the semiconductor substrate 300.

As shown in FIG. 1R, the chip-containing structure 30 further includes a dielectric bonding structure 306 and multiple metal bonding structures 308, in accordance with some embodiments. In some embodiments, the metal bonding structures 308 penetrate through the dielectric bonding structure 306 and the front-side interconnection portion 304. The metal bonding structures 308 may establish electrical connections to the through-chip vias 310. The material and formation method of the dielectric bonding structure 306 may be the same as or similar to those of the dielectric bonding structure 124. The material and formation method of the metal bonding structures 308 may be the same as or similar to those of the metal bonding structures 132.

As shown in FIG. 1R, the chip-containing structure 30 further includes a dielectric bonding structure 312 and multiple metal bonding structures 314, in accordance with some embodiments. In some embodiments, the metal bonding structures 314 penetrate through the dielectric bonding structure 312. The metal bonding structures 308 may establish electrical connections to the through-chip vias 310. The material and formation method of the dielectric bonding structure 312 may be the same as or similar to those of the dielectric bonding structure 124. The material and formation method of the metal bonding structures 314 may be the same as or similar to those of the metal bonding structures 132.

Similar to the formation of the metal bonding structures 132, a planarization process such as a CMP process is used to ensure that the surfaces of the metal bonding structures 308 and the surface of the dielectric bonding structure 306 are substantially coplanar. Similarly, another CMP process may be used to ensure that the surfaces of the metal bonding structures 314 and the surface of the dielectric bonding structure 312 are substantially coplanar. The planarization processes may help to provide the chip-containing structure 30 with highly planarized bonding surfaces.

In some embodiments, the chip-containing structure 30 and the reconstructed thermal conductive wafer 20 are bonded together through direct bonding, as shown in FIG. 1R. The direct bonding may be a hybrid bonding that includes metal-to-metal bonding and dielectric-to-dielectric bonding. For example, the dielectric bonding structures 124 and 306 are in direct contact with each other and together form the dielectric-to-dielectric bonding. The metal bonding structures 132 and 308 are in direct contact with each other and together form the metal-to-metal bonding. In some embodiments, there is no tin-containing solder elements formed between the chip-containing structure 30 and the reconstructed thermal conductive wafer 20.

In some embodiments, the chip-containing structure 30 is placed directly on the dielectric bonding structure 124 and the metal bonding structures 132 of the reconstructed thermal conductive wafer 20. As a result, the dielectric bonding structure 306 of the chip-containing structure 30 is in direct contact with the dielectric bonding structure 124 of the reconstructed thermal conductive wafer 20. The metal bonding structures 308 of the chip-containing structure 30 are in direct contact with the metal bonding structures 132 of the reconstructed thermal conductive wafer 20.

As mentioned above, before the placing of the chip-containing structure 30, planarization processes are performed, so as to provide highly planarized bonding surfaces. In some embodiments, there is no gap between the dielectric bonding structures 124 and 306. In some embodiments, there is no gap between the metal bonding structures 132 and 308. In some embodiments, a thermal operation is then used to enhance the bonding between the metal bonding structures 132 and 308. The temperature of the thermal operation may within a range from about 100 degrees C. to about 500 degrees C.

In some embodiments, the chip-containing structure 30 is bonded after the thermal conductive element 104′ is formed. This sequence prevents the chip-containing structure 30 from being negatively affected by the high-temperature processes used in forming the thermal conductive element 104′, ensuring its performance and reliability.

As shown in FIG. 1S, a carrier substrate 316 is attached to the chip-containing structure 30 through an adhesive layer 315, in accordance with some embodiments. The carrier substrate 316 may be a semiconductor wafer, a glass wafer, or the like.

Afterwards, the structure shown in FIG. 1S is turned upside down. Then, the bonding layer 118 and the carrier substrate 116 are removed. A thinning process, such as a CMP process, is performed to remove the bonding layer 106 and a portion of the protective layer 120. As a result, the thermal conductive element 104′ and the metal bonding structures 132 are exposed, as shown in FIG. 1T in accordance with some embodiments. In some embodiments, the surfaces of the protective layer 120, the thermal conductive element 104′, and the metal bonding structures 132 are substantially coplanar.

As shown in FIG. 1U, a dielectric bonding structure 318 and multiple metal bonding structures 320 are formed over the protective layer 120 and the thermal conductive element 104′, in accordance with some embodiments. In some embodiments, the metal bonding structures 320 penetrate through the dielectric bonding structure 318. The metal bonding structures 320 may be electrically connected to the metal bonding structures 132. The material and formation method of the dielectric bonding structure 318 may be the same as or similar to those of the dielectric bonding structure 124. The material and formation method of the metal bonding structures 320 may be the same as or similar to those of the metal bonding structures 132.

Similar to the formation of the metal bonding structures 314, a planarization process such as a CMP process is used to ensure that the surfaces of the metal bonding structures 320 and the surface of the dielectric bonding structure 320 are substantially coplanar. The planarization processes may help to provide a highly planarized bonding surface, which facilitates the subsequent bonding process.

As shown in FIG. 1V, the adhesive layer 315 and the carrier substrate 316 are then removed, in accordance with some embodiments. As a result, a package structure 1000 is formed. The package structure 1000 includes the chip-containing structure 30 and the reconstructed thermal conductive wafer 20. In some embodiments, a saw operation is used to separate the package structure 1000 into multiple smaller package structures. The smaller package structures may further be bonded to another larger package structure. For example, a chip-on-wafer (CoW) bonding process may be used.

In some embodiments, the chip-containing structure 30 and the protective layer 120 are cut through along the predetermined scribe line regions during the saw operation. The protective layer 120 prevents the thermal conductive element 104′ from being cut or damaged during the saw operation, ensuring the quality and reliability of the thermal conductive element 104′. The heat dissipation of the chip-containing structure 30 may thus be improved.

Alternatively, in some other embodiments, the package structure 1000 is not sawed. The package structure 1000 may be directly bonded with other package structures. For example, a wafer-on-wafer (WoW) bonding process may be used.

Many variations and/or modifications can be made to embodiments of the disclosure. In some embodiments, two or more package structures that are similar to that shown in FIG. 1V are integrated to form a system-on-integrated-chips (SoIC) package structure. For the system-on-integrated-chips package structure, multiple chip-containing structures (or chiplets) are stacked and bonded together to form electrical connections between these chip-containing structures. In some embodiments, each of the chip-containing structures are system-on-chip (SoC) chips that include multiple functions. In some embodiments, multiple thermal conductive elements are placed between the chip-containing structures, greatly improving the heat dissipation of the SoIC package structure.

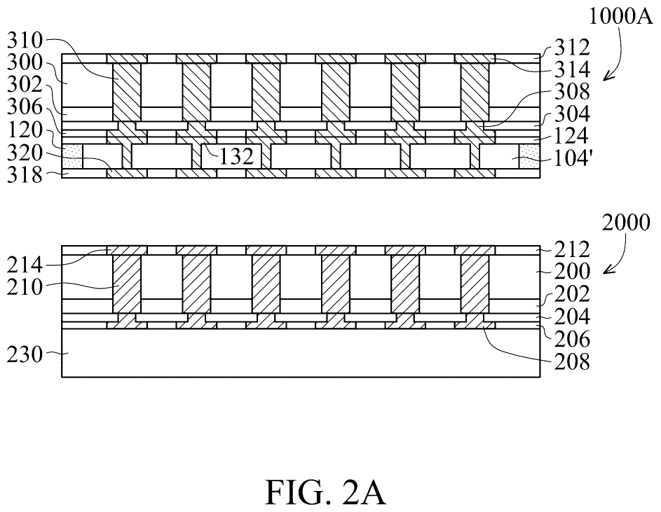

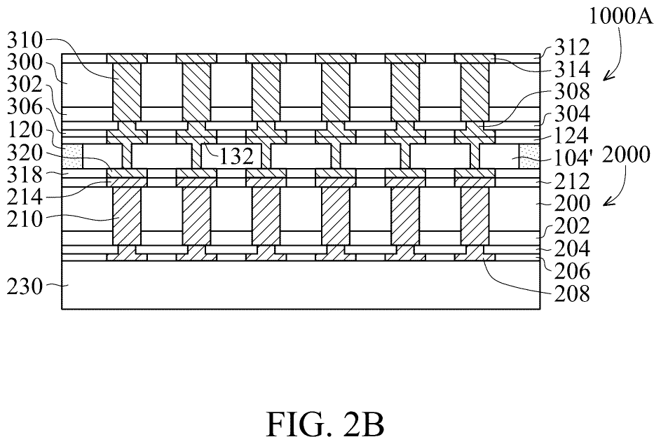

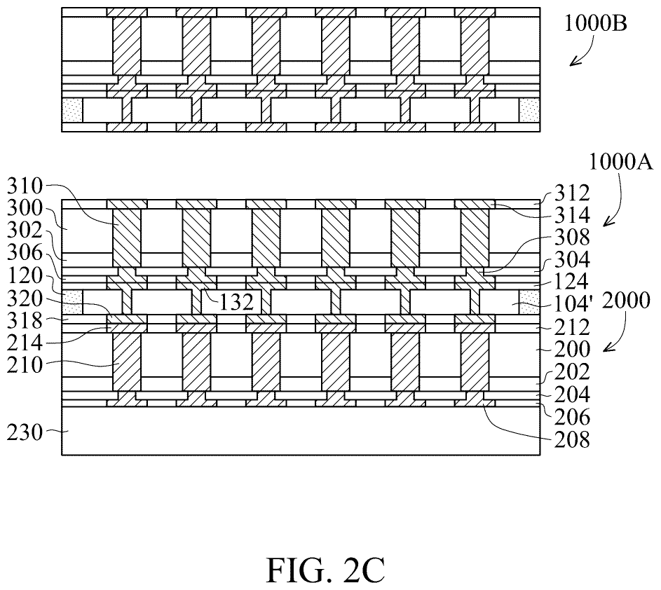

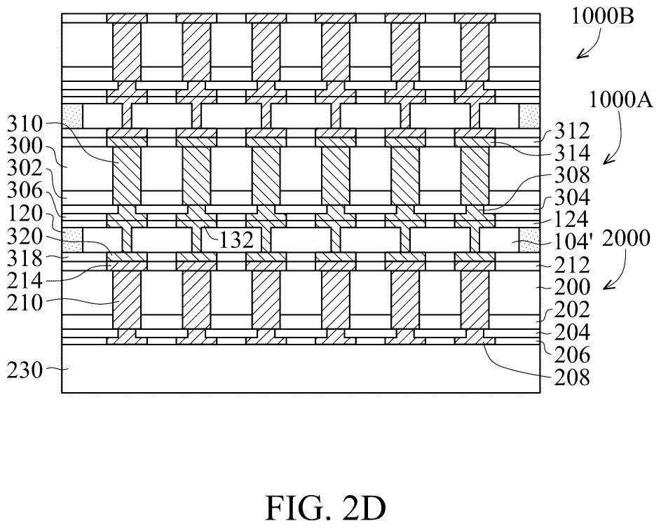

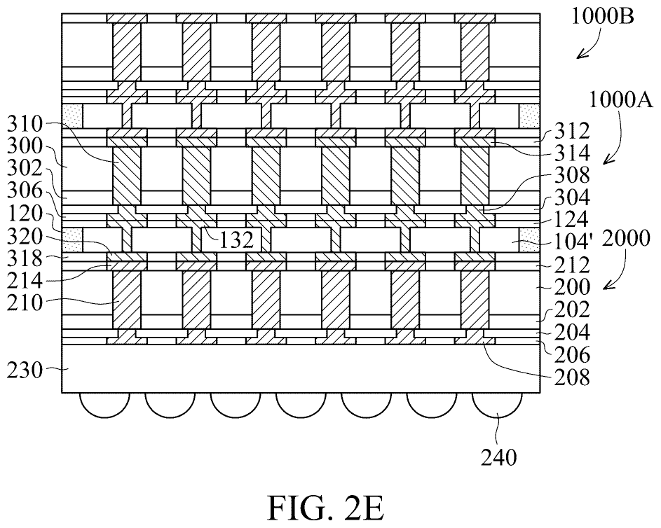

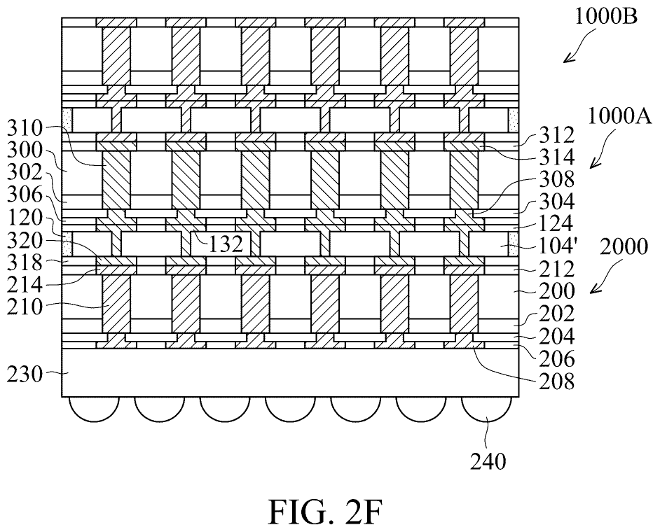

FIGS. 2A-2F are cross-sectional views of various stages of a process for forming a portion of a package structure, in accordance with some embodiments. As shown in FIG. 2A, a chip-containing structures 1000A and 2000 are provided. The chip-containing structure 1000A is positioned over the chip-containing structure 2000 and is prepared for bonding. In some embodiments, the chip-containing structure 1000A is similar to the structure shown in FIG. 1V. In some embodiments, the chip-containing structure 1000A includes a single semiconductor chip. In some other embodiments, the chip-containing structure 1000A includes a semiconductor wafer with multiple semiconductor chips. In some embodiments, the chip-containing structure 2000 is a semiconductor wafer that includes multiple semiconductor chips.

In some embodiments, the chip-containing structure 2000 includes a semiconductor substrate 200. In some embodiments, the semiconductor substrate 200 is a bulk semiconductor substrate, such as a semiconductor wafer. The semiconductor substrate 200 may include silicon or other elementary semiconductor materials such as germanium. The semiconductor substrate 200 may be un-doped or doped (e.g., p-type, n-type, or a combination thereof). In some embodiments, the semiconductor substrate 200 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 200 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 200 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 200 includes a multi-layered structure. For example, the semiconductor substrate 200 includes a silicon-germanium layer formed on a bulk silicon layer.

Various device elements are formed in or over the semiconductor substrate 200. In some embodiments, the device elements are formed in the device region 202, as shown in FIG. 2A. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or other suitable elements. Various processes may be used to form the various device elements, including deposition, etching, implantation, photolithography, annealing, and/or other suitable processes.

In some embodiments, the chip-containing structure 2000 includes a front-side interconnection portion 204. The front-side interconnection portion 204 includes multiple dielectric layers and multiple conductive features surrounded by the dielectric layers. The conductive features may include conductive contacts, conductive lines, and conductive vias.

The device elements in the device region 202 of the chip-containing structure 2000 may be interconnected by the front-side interconnection portion 204 to form integrated circuit devices, such as a logic device, a memory device (e.g., static random access memory, SRAM), a radio frequency (RF) device, an input/output (I/O) device, a system-on-chip (SoC) device, one or more other types of devices, or a combination thereof.

In some embodiments, the chip-containing structure 2000 includes multiple through-chip vias 210, as shown in FIG. 2A. Each of the through-chip vias 210 may be electrically connected to one or more of the conductive features formed in the front-side interconnection portion 204. In some embodiments, an insulating layer is formed between the semiconductor substrate 200 and the through-chip vias 210, so as to prevent short circuiting between the through-chip vias 210 and the semiconductor substrate 200.

As shown in FIG. 2A, the chip-containing structure 2000 further includes a dielectric layer 206 and multiple conductive features 208, in accordance with some embodiments. In some embodiments, the conductive features 208 are electrically connected to the conductive features formed in the front-side interconnection portion 204 and/or the through-chip vias 210.

As shown in FIG. 2A, the chip-containing structure 2000 further includes a redistribution structure 230, in accordance with some embodiments. The redistribution structure 230 may include multiple insulating layers and multiple conductive features. The conductive features of the redistribution structure 230 may establish electrical connections to the conductive features 208.

As shown in FIG. 2A, the chip-containing structure 2000 further includes a dielectric bonding structure 212 and multiple metal bonding structures 214, in accordance with some embodiments. The conductive features 208 may establish electrical connections to the through-chip vias 210. The material and formation method of the dielectric bonding structure 212 may be the same as or similar to those of the dielectric bonding structure 124. The material and formation method of the metal bonding structures 214 may be the same as or similar to those of the metal bonding structures 132.

Similar to the formation of the metal bonding structures 132, a planarization process such as a CMP process is used to ensure that the surfaces of the conductive features 208 and the surface of the dielectric layer 206 are substantially coplanar. The planarization processes create a highly planarized bonding surface on the chip-containing structure 2000, facilitating its subsequent bonding process with the chip-containing structure 1000A.

As shown in FIG. 2B, the chip-containing structures 1000A and 2000 are bonded together through direct bonding, in accordance with some embodiments. The direct bonding may be a hybrid bonding that includes metal-to-metal bonding and dielectric-to-dielectric bonding. For example, the dielectric bonding structures 212 and 318 are in direct contact with each other and together form the dielectric-to-dielectric bonding. The metal bonding structures 214 and 320 are in direct contact with each other and together form the metal-to-metal bonding. In some embodiments, there is no tin-containing solder elements formed between the chip-containing structures 2000 and 1000A.

In some embodiments, the chip-containing structure 1000A is placed directly on the dielectric bonding structure 212 and the metal bonding structures 214 of the chip-containing structure 2000. As mentioned above, before the placing of the chip-containing structure 1000A, planarization processes are performed, so as to provide highly planarized bonding surfaces. In some embodiments, there is no gap between the dielectric bonding structures 212 and 318. In some embodiments, once the dielectric bonding structures 212 and 318 come into direct contact, they bond together due to their highly planarized surfaces. In some embodiments, there is no gap between the metal bonding structures 214 and 320. In some embodiments, a thermal operation is then used to enhance the bonding between the metal bonding structures 214 and 320. The temperature of the thermal operation may within a range from about 100 degrees C. to about 500 degrees C.

As shown in FIG. 2C, similar to the embodiments illustrated in FIG. 2A, a chip-containing structure 1000B is positioned over the chip-containing structure 1000A and is prepared for bonding. The chip-containing structure 1000B may be the same as or similar to the chip-containing structure 1000A.

As shown in FIG. 2D, similar to the embodiments illustrated in FIG. 2B, the chip-containing structure 1000B is directly bonded to the chip-containing structure 1000A, in accordance with some embodiments. In some embodiments, the bonding between the chip-containing structures 1000A and 1000B includes metal-to-metal bonding and dielectric-to-dielectric bonding. In some embodiments, there is no tin-containing solder elements formed between the chip-containing structures 1000A and 1000B.

As shown in FIG. 2E, conductive bump 240 are formed, in accordance with some embodiments. The conductive bump 240 may include a solder material. The solder material may be a tin-containing material. The tin-containing material may further include copper, silver, gold, aluminum, lead, one or more other suitable materials, or a combination thereof. In some embodiments, the solder material is lead-free.

As shown in FIG. 2F, a saw operation is used to separate the structure shown in FIG. 2E into multiple package structures. One of the package structures is shown in FIG. 2F. In some embodiments, the edges of the protective layers 120 and the chip-containing structure 1000A and 1000B are vertically aligned.

The package structure may function as a system on integrated chips (SoIC) package structure that may further be integrated into another package. The package may include multiple chip structures bonded to an interposer substrate that is further bonded to another substrate. Alternatively, the package may include multiple chip structures surrounded by a protective layer and a redistribution structure formed on the chip structures and the protective layer.

In some embodiments, the chip-containing structures 1000A, 1000B, and 2000 and the protective layers 120 of the chip-containing structures 1000A and 1000B are cut through along the predetermined scribe line regions during the saw operation. The protective layers 120 prevent the thermal conductive elements 104′ from being cut or damaged during the saw operation, ensuring the quality and reliability of the thermal conductive elements 104′. In some embodiments, the thermal conductive elements 104′ exhibit higher thermal conductivity than copper. This high thermal conductivity improves the heat dissipation of the package structure shown in FIG. 2F, leading to enhanced performance and reliability.

Embodiments of the disclosure form a package structure that includes a chip-containing structure bonded to a thermal conductive element exhibiting higher thermal conductivity than copper. Multiple thermal conductive elements are placed over a carrier wafer to form a reconstructed thermal conductive wafer. A protective layer is formed to laterally surround and to protect the thermal conductive elements. The reconstructed thermal conductive wafer is then bonded to another semiconductor wafer with logic devices. The bonding is performed after the thermal conductive elements are formed. This sequence prevents the device elements from being negatively affected by the high-temperature processes used in forming the thermal conductive elements, ensuring the performance and reliability. During the subsequent packaging processes that involve one or more saw operations, the protective layer prevent the thermal conductive elements from being cut and damaged, ensuring the quality and reliability of the thermal conductive elements. The performance and reliability of the package structure are thus greatly improved.

In accordance with some embodiments, a method for forming a package structure is provided. The method includes forming a diamond-containing material layer over a first carrier substrate and patterning the diamond-containing material layer to form multiple diamond-containing elements that are spaced apart from each other. The method also includes removing the first carrier substrate and disposing the diamond-containing elements over a second carrier substrate. The method further includes forming a protective layer over the second carrier substrate, and the protective layer laterally surrounds the diamond-containing elements. In addition, the method includes bonding a chip-containing structure to a first diamond-containing element of the diamond-containing elements through dielectric-to-dielectric bonding and metal-to-metal bonding.

In accordance with some embodiments, a method for forming a package structure is provided. The method includes forming multiple patterned material elements over a carrier substrate, and the patterned material elements are more thermal conductive than copper. The method also includes forming a protective layer laterally surrounding each of the patterned material elements. The method further includes bonding a chip-containing structure to a first patterned material element of the patterned material elements through dielectric-to-dielectric bonding and metal-to-metal bonding.

In accordance with some embodiments, a package structure is provided. The package structure includes a first chip-containing structure and a second chip-containing structure over the first chip-containing structure. The package structure also includes a material layer between the first chip-containing structure and the second chip-containing structure. The material layer has a thermal conductivity greater than 400 W/mK. The package structure further includes a protective layer laterally surrounding the material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
forming a diamond-containing material layer over a first carrier substrate;
patterning the diamond-containing material layer to form a plurality of diamond-containing elements that are spaced apart from each other;
removing the first carrier substrate;
disposing the diamond-containing elements over a second carrier substrate;
forming a protective layer over the second carrier substrate, wherein the protective layer laterally surrounds the diamond-containing elements; and
bonding a chip-containing structure to a first diamond-containing element of the diamond-containing elements through dielectric-to-dielectric bonding and metal-to-metal bonding.

2. The method for forming a package structure as claimed in claim 1, further comprising:
forming a first dielectric bonding structure and a plurality of first metal bonding structures over the first diamond-containing element before the chip-containing structure is bonded to the first diamond-containing element, wherein:
surfaces of the first metal bonding structures and a surface of the first dielectric bonding structure are substantially coplanar,
the chip-containing structure has a plurality of second metal bonding structures and a second dielectric bonding structure laterally surrounding the second metal bonding structures,
surfaces of the second metal bonding structures and a surface of the second dielectric bonding structure are substantially coplanar,
the first metal bonding structures and the second metal bonding structures are directly bonded together after the chip-containing structure is bonded to the first diamond-containing element, and
the first dielectric bonding structure and the second dielectric bonding structure are directly bonded together after the chip-containing structure is bonded to the first diamond-containing element.

3. The method for forming a package structure as claimed in claim 2, further comprising:
partially removing the first diamond-containing element to form a plurality of through-holes in the first diamond-containing element after the protective layer is formed, wherein the first metal bonding structures are formed to fill the through-holes.

4. The method for forming a package structure as claimed in claim 1, further comprising:
cutting through the chip-containing structure and the protective layer using a saw operation.

5. The method for forming a package structure as claimed in claim 4, wherein the first diamond-containing element is not cut during the saw operation.

6. The method for forming a package structure as claimed in claim 1, further comprising:
bonding a second chip-containing structure to a second diamond-containing element through dielectric-to-dielectric bonding and metal-to-metal bonding, wherein the second diamond-containing element contains diamond; and
bonding the second diamond-containing element to the chip-containing structure through dielectric-to-dielectric bonding and metal-to-metal bonding.

7. The method for forming a package structure as claimed in claim 6, further comprising:
forming a second protective layer laterally surrounding the second diamond-containing element before the second diamond-containing element is bonded to the chip-containing structure; and
cutting through the chip-containing structure, the second chip-containing structure, the protective layer, and the second protective layer using a saw operation.

8. The method for forming a package structure as claimed in claim 7, wherein the first diamond-containing element and the second diamond-containing element are not cut during the saw operation.

9. The method for forming a package structure as claimed in claim 1, further comprising:
forming a protective material layer over the second carrier substrate and the diamond-containing elements;
partially removing the protective material layer to form an opening exposing the first diamond-containing element; and
planarizing the protective material layer after the opening is formed, wherein a remaining portion of the protective material layer forms the protective layer, and top surfaces of the protective layer and the first diamond-containing element are substantially coplanar.

10. The method for forming a package structure as claimed in claim 1, wherein the first carrier substrate and the second carrier substrate are semiconductor wafers with different diameters.

11. A method for forming a package structure, comprising:
forming a plurality of patterned material elements over a carrier substrate, wherein the patterned material elements are more thermal conductive than copper;
forming a protective layer laterally surrounding each of the patterned material elements; and
bonding a chip-containing structure to a first patterned material element of the patterned material elements through dielectric-to-dielectric bonding and metal-to-metal bonding.

12. The method for forming a package structure as claimed in claim 11, further comprising:
forming a first dielectric bonding structure and a plurality of first metal bonding structures over the first patterned material element before the chip-containing structure is bonded to the first patterned material element, wherein:
surfaces of the first metal bonding structures and a surface of the first dielectric bonding structure are substantially coplanar,
the chip-containing structure has a plurality of second metal bonding structures and a second dielectric bonding structure laterally surrounding the second metal bonding structures,
surfaces of the second metal bonding structures and a surface of the second dielectric bonding structure are substantially coplanar,
the first metal bonding structures and the second metal bonding structures are directly bonded together after the chip-containing structure is bonded to the first patterned material element, and
the first dielectric bonding structure and the second dielectric bonding structure are directly bonded together after the chip-containing structure is bonded to the first patterned material element.

13. The method for forming a package structure as claimed in claim 12, further comprising:
partially removing the first patterned material element to form a plurality of through-holes in the first patterned material element after the protective layer is formed, wherein the first metal bonding structures are formed to fill the through-holes.

14. The method for forming a package structure as claimed in claim 11, further comprising:
cutting through the chip-containing structure and the protective layer using a saw operation.

15. The method for forming a package structure as claimed in claim 14, wherein the first patterned material element is not cut by the saw operation.

16. A package structure, comprising:
a first chip-containing structure;
a second chip-containing structure over the first chip-containing structure;
a material layer between the first chip-containing structure and the second chip-containing structure, wherein the material layer has a thermal conductivity greater than 400 W/mK; and
a protective layer laterally surrounding the material layer.

17. The package as claimed in claim 16, wherein the material layer contains carbon.

18. The package as claimed in claim 16, further comprising:
a first dielectric bonding structure and a plurality of first metal bonding structures between the material layer and the first chip-containing structure, wherein surfaces of the first metal bonding structures and a surface of the first dielectric bonding structure are substantially coplanar; and
a plurality of second metal bonding structures and a second dielectric bonding structure laterally surrounding the second metal bonding structures, wherein:
surfaces of the second metal bonding structures and a surface of the second dielectric bonding structure are substantially coplanar,
the second dielectric bonding structure is between the first chip-containing structure and the first dielectric bonding structure,
the first metal bonding structures and the second metal bonding structures are directly bonded together, and
the first dielectric bonding structure and the second dielectric bonding structure are directly bonded together.

19. The package as claimed in claim 18, wherein edges of the protective layer and the first chip-containing structure are vertically aligned.

20. The package as claimed in claim 16, wherein the second chip-containing structure extends across outermost edges of the thermal conductive element.
